(19) United States
(12) Patent Application Publication
(10) Pub. No.: US 2020/0256915 A1
(43) Pub. Date: Aug. 13, 2020

(54) INLINE MONITORING TEST STRUCTURE

(71) Applicant: QUALCOMM Incorporated, San Diego, CA (US)

(72) Inventors: Youn Sung CHOI, San Diego, CA (US); Fadoua CHAFIK, San Diego, CA (US); Kwanyong LIM, San Diego, CA (US)

(21) Appl. No.: 16/274,158

(22) Filed: Feb. 12, 2019

(51) Int. Cl. G01R 31/28; H01L 23/48; H03K 19/0185; H01L 21/66; H01L 27/092

(52) U.S. Cl. CPC G01R 31/2853; H01L 23/481; H01L 27/0924; H01L 22/34; H03K 19/018585

(57) ABSTRACT

An on-chip test structure has an NMOS transistor (N-type metal oxide semiconductor transistor). The NMOS transistor includes a first source/drain contact and a first gate contact formed in an N-type source/drain opening. The on-chip test structure also has a PMOS transistor (P-type metal oxide semiconductor transistor) adjacent to the NMOS transistor. The PMOS transistor includes a second source/drain contact and a second gate contact formed in a P-type source/drain opening. A distance between the N-type source/drain opening and the P-type source/drain opening is offset relative to a distance between other N-type source/drain openings and P-type source/drain openings, outside the on-chip test structure, that are configured according to a standard technology specification.

### FIELD

The present disclosure generally relates to integrated circuits (ICs). More specifically, the present disclosure relates to an inline monitoring test structure design for early detection of interlayer metal defects on a chip.

### BACKGROUND

As integrated circuit (IC) technology advances, device (e.g., semiconductor device) geometries are reduced. Reducing the geometry and “pitch” (e.g., spacing) between integrated circuit devices may cause the integrated circuit devices to interfere with each other and affect proper operation.

These integrated circuit devices may include different types of transistors. For example, the devices may include planar transistors, fin-based transistors, or gate all around (GAA) transistors. Fin-based transistors are three-dimensional structures on the surface of a semiconductor substrate. A fin-based transistor, which may be a fin-based metal oxide semiconductor field-effect transistor (MOSFET), may be referred to as a FinFET. A nanowire field-effect transistor (nanowire FET) is also a three-dimensional structure on the surface of a semiconductor substrate. A nanowire FET includes doped portions of the nanowire that contact a channel region and serve as the source and drain regions of the device. A nanowire FET is also an example of a MOSFET device.

Fabrication of semiconductor integrated circuits specifies that precisely controlled quantities of impurities be introduced into small regions of a semiconductive substrate and that these regions be interconnected to create microelectronic components and integrated circuits. As a result, the manufacture of semiconductor integrated circuits involves a loss of chip yield due to the presence of various defects. An example of a defect that may occur when conductive layers are formed on an integrated circuit is extra material defects. Extra material defects may occur when the conductive structures include material extending beyond predefined boundaries. Such material may extend to another conductive structure, causing a short to be formed between the two conductive structures.

### SUMMARY

An on-chip test structure has an NMOS transistor (N-type metal oxide semiconductor transistor). The NMOS transistor includes a first source/drain contact and a first gate contact formed in an N-type source/drain opening. The on-chip test structure also has a PMOS transistor (P-type metal oxide semiconductor transistor) adjacent to the NMOS transistor. The PMOS transistor includes a second source/drain contact and a second gate contact formed in a P-type source/drain opening. A distance between the N-type source/drain opening and the P-type source/drain opening is offset relative to a distance between other N-type source/drain openings and P-type source/drain openings, outside the on-chip test structure, that are configured according to a standard technology specification.

An on-chip test structure has a conductive contact structure in a conductive layer of a metal oxide semiconductor (MOS) transistor. The conductive contact structure includes a first set of conductive branches orthogonally coupled to a first conductive terminal. The conductive contact structure also includes a second set of conductive branches orthogonally coupled to a second conductive terminal. The first set of conductive branches are interdigitated with the second set of conductive branches. The first set of conductive branches and/or the second set of conductive branches have branch to branch distance variation.

An on-chip test structure has a conductive contact structure in a conductive layer of a metal oxide semiconductor (MOS) transistor. The conductive contact structure includes a first set of conductive branches orthogonally coupled to a first conductive terminal. The conductive contact structure also includes a second set of conductive branches orthogonally coupled to a second conductive terminal. The first set of conductive branches are interdigitated with the second set of conductive branches. Vias are also connected to the first set of conductive branches and the second set of conductive branches. A subset of the vias are offset relative to other vias that are configured according to a standard technology specification.

A method of making an on-chip test structure includes fabricating an NMOS transistor (N-type metal oxide semiconductor transistor). The NMOS transistor includes a first source/drain contact and a first gate contact formed in an N-type source/drain opening. The method also includes fabricating a PMOS transistor (P-type metal oxide semiconductor transistor) adjacent to the NMOS transistor. The PMOS transistor includes a second source/drain contact and a second gate contact in a P-type source/drain opening. A distance between the N-type source/drain opening and the P-type source/drain opening is offset relative to a distance between other N-type source/drain openings and P-type source/drain openings, outside the on-chip test structure, that are configured according to a standard technology specification.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates a perspective view of a semiconductor wafer.

FIG. 2 illustrates a cross-sectional view of a die.

FIG. 3 illustrates a cross-sectional view of a metal oxide semiconductor field-effect transistor (MOSFET) device.

FIG. 4 illustrates a fin field-effect transistor (FinFET).

FIGS. 5A-5F are exemplary diagrams illustrating cross-sections of stages of a process of fabricating source/drain regions for a P-type fin field-effect transistor (FinFET) of an integrated circuit and source/drain regions for an N-type FinFET of the integrated circuit.

FIG. 6A illustrates a top view of an integrated circuit designed according to minimum design ground rules or standard technology specifications.

FIG. 6B-6G illustrate top views of an integrated circuit where one or more distances between elements of the N-type transistor and the P-type transistor are adjusted below a minimum specified technology ground rule, according to aspects of the present disclosure.

FIG. 7A illustrates an on-chip test structure having a double comb structure where vias associated with fingers of the comb structure are misaligned, according to aspects of the present disclosure.

FIG. 7B illustrates an on-chip test structure having a double comb structure where the fingers of the comb structure are misaligned, according to aspects of the present disclosure.

FIG. 8 is a flow diagram illustrating a method of fabricating a conductive test structure, in accordance with aspects of the present disclosure.

FIG. 9 is a block diagram showing an exemplary wireless communications system in which a configuration of the disclosure may be advantageously employed.

FIG. 10 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

The process flow for semiconductor fabrication (e.g., complementary metal oxide semiconductor (CMOS) fabrication) of an integrated circuit device may include front-end-of-line (FEOL) processes, middle-of-line (MOL) processes, and back-end-of-line (BEOL) processes. These processes result in substantially planar layers atop the semiconductor substrate. The FEOL processes may include the set of process steps that form the active devices, such as transistors and diodes. For example, FEOL processes include wafer preparation, isolation, well formation, gate patterning, spacers, and dopant implantation.

The MOL processes may include the set of process steps that enable connection of the transistors to BEOL interconnects. These steps include silicidation and contact formation as well as stress introduction. For example, access to devices, formed during a front-end-of line (FEOL) process, is conventionally provided during middle-of-line (MOL) processing that creates contacts between the gates and source/drain regions of the devices and back-end-of-line (BEOL) interconnect layers (e.g., M1, M2, etc.). The BEOL processes may include the set of process steps that form the interconnects that tie the independent transistors and form circuits. The BEOL processes include forming interconnects and dielectric layers for coupling to the FEOL devices.

It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably.

As technology scaling continues, associated shrinking of integrated circuit device elements creates latent defects that arise during fabrication of the integrated circuits. For example, latent defects are defects that are not detectable at fabrication screening or at time-zero (TO) screening (e.g., wafer or die probe, or wafer sort) but cause failure either at burn-in (which is a very expensive screen test) or in the field. The latent defect significantly affects logic and radio frequency (RF) circuit performance because spacer size shrinks with each technology generation. For example, shrinking of a gate pitch reduces spacer area between the source/drain trench (CA) contacts and the gate stack. This causes a dramatic increase in the latent defects. Because the latent defects, however, are marginal and can cause circuit failure over time, it is especially important for automotive applications that such defects be minimized or reduced at the source (e.g., silicon chip processing stage or initial electrical testing stage), prior to shipping to customers or prior to expensive screening or potential return merchandise authorizations (RMAs).

Chip designs for automotive applications are specified to pass stringent reliability criteria to meet one defect part per million (DPPM), which specifies extensive and expensive screening/testing of latent defects post-fabrication. Some of the testing/screening includes sophisticated screening at wafer probe, burn-in stress and system-level testing, and extensive automatic test equipment (ATE) testing. These tests can be at a wafer and package level, across different temperature, voltage, and ambient conditions. However, extensive testing at the wafer and package level is expensive. Other solutions include a Bin1 outlier screening methodology (e.g., dynamic part averaging testing (DPAT) and a good die/bad neighborhood (GDBN) methodology), which causes significant yield loss.

These extensive and expensive screenings for latent defects post-fabrication (e.g., sophisticated screening at wafer probe, burn-in, and extensive automatic test equipment (ATE) testing) do not catch all existing latent defects. Thus, shipped units are exposed to potential on-field failure. Accordingly, continued reduction in latent defects for consumer chip designs is desirable. For example, process innovations are desirable to reduce the incidence of latent defects to further reduce return merchandise authorization to near-zero levels.

Aspects of the present disclosure are directed to a conductive interconnect test structure or on-chip test structure to detect and prevent latent defects. In one aspect, the on-chip test structure includes an N-type metal oxide semiconductor (NMOS) transistor formed in an N-type source/drain opening including a first source/drain contact and a first gate contact. The on-chip test structure also include a P-type metal oxide semiconductor (PMOS) transistor adjacent to the NMOS transistor. The PMOS transistor is formed in a P-type source/drain opening including a second source/drain contact and a second gate contact. A distance between the N-type source/drain opening and the P-type source/drain opening is offset relative to a distance between other N-type source/drain openings and P-type source/drain openings outside the on-chip test structure, that are configured according to a pre-defined/standard technology specification.

For example, the distance between the N-type source/drain opening and the P-type source/drain opening and/or their elements (e.g., source/drain/gate) are offset such that they are outside the scope of the standard technology specification for device spacing. Thus, a width of the N-type source/drain opening may be reduced outside of a scope of the standard technology specification to offset the distance between the N-type source/drain opening and the P-type source/drain opening. Similarly, a width of the P-type source/drain opening may be reduced outside of a scope of the standard technology specification to offset the distance between the N-type source/drain opening and the P-type source/drain opening.

Other ways to create misalignment in the on-chip test structure include reducing a distance between the first source/drain contact and the second source/drain contact. For example, the first source/drain contact may be misaligned relative to the first gate contact and/or the second source/drain contact is misaligned relative to the second gate contact to offset the distance between the NMOS transistor and the PMOS transistor.

In some aspects, the on-chip test structure includes a conductive contact structure in a conductive layer of an N-type metal oxide semiconductor (NMOS) transistor or a P-type metal oxide semiconductor (PMOS) transistor. The conductive contact structure includes a first set of conductive branches orthogonally coupled to a first conductive terminal and a second set of conductive branches orthogonally coupled to a second conductive terminal. The first set of conductive branches is interdigitated with the second set of conductive branches. The first set of conductive branches and/or the second set of conductive branches have branch to branch distance variation.

For example, at least a subset of the first set of conductive branches and/or the second set of conductive branches are shifted to the left or to the right to vary the branch to branch distance of the first set of conductive branches and/or the second set of conductive branches. The conductive layer includes a back-end-of-line (BEOL) layer or a middle-of-line (MOL) layer.

In some aspects, the on-chip test structure includes a conductive contact structure in a conductive layer of an N-type metal oxide semiconductor (NMOS) transistor or a P-type metal oxide semiconductor (PMOS) transistor. The conductive contact structure includes a first set of conductive branches orthogonally coupled to a first conductive terminal and a second set of conductive branches orthogonally coupled to a second conductive terminal. The first set of conductive branches is interdigitated with the second set of conductive branches. The on-chip test structure further includes vias connected to the first set of conductive branches and the second set of conductive branches. A subset of the vias are offset relative to other vias that are configured according to the standard technology specification.

For example, the subset of the vias are shifted to the left or to the right to offset the subset of the vias relative to the other vias. The conductive layer includes a back-end-of-line (BEOL) layer or a middle-of-line (MOL) layer.

Detecting the latent defects during the initial electrical testing stage (e.g., wafer-level E-test) avoids more expensive screening later or potential RMAs due to test escapes.

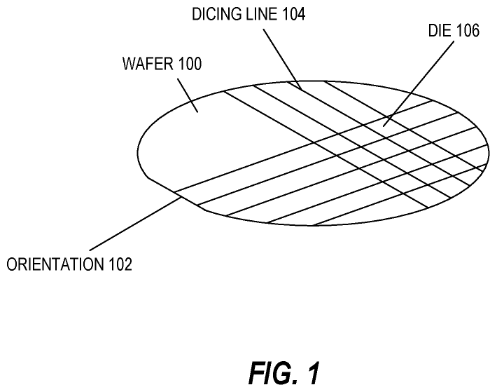

FIG. 1 illustrates a perspective view of a wafer. A wafer 100 may be a semiconductor wafer, or may be a substrate material with one or more layers of material on a surface of the wafer 100. For explanatory purposes a chip, as described, may include a wafer or a die. The chip may include the on-chip test structure. Accordingly, the chip includes the capability of detecting latent defects during the initial electrical testing stage. The wafer 100 may be a compound material, such as gallium arsenide (GaAs) or gallium nitride (GaN), a ternary material such as indium gallium arsenide (InGaAs), quaternary materials, silicon, quartz, glass, or any material that can be a substrate material. Although many of the materials may be crystalline in nature, polycrystalline or amorphous materials may also be used for the wafer 100. For example, various options for the substrate include a glass substrate, a semiconductor substrate, a core laminate substrate, a coreless substrate, a printed circuit board (PCB) substrate, or other like substrates.

The wafer 100, or layers that are coupled to the wafer 100, may be supplied with materials that enable formation of different types of electronic devices in or on the wafer 100. In addition, the wafer 100 may have an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100, assuming a semiconductor wafer.

Once the wafer 100 has been processed as desired, the wafer 100 is divided up along dicing lines 104. For example, once fabrication of integrated circuits on the wafer 100 is complete, the wafer 100 is divided up along the dicing lines 104, which may be referred to as “dicing streets.” The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form the die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

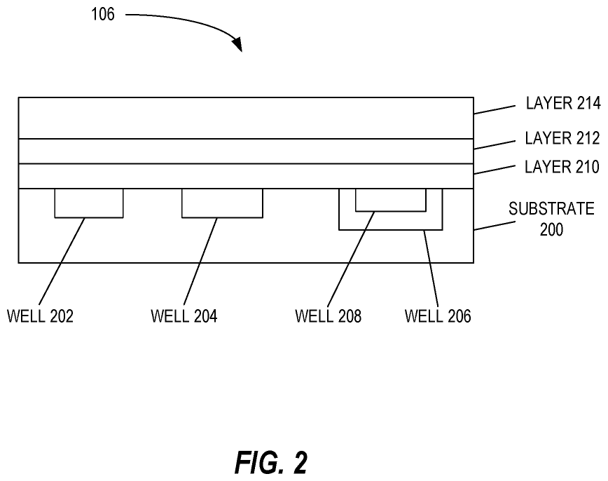

FIG. 2 illustrates a cross-sectional view of a die 106. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200. Alternatively, the substrate may be a semi-insulating substrate, including compound semiconductor transistors. The substrate 200 may include one or more layers of material on a surface of the substrate 200 that includes the on-chip test structure. Accordingly, a chip including the substrate and the on-chip test structure has the capability of detecting latent defects during the initial electrical testing stage.

Within a substrate 200 (e.g., a semiconductor substrate), there may be wells 202 and 204, which may be the source and/or drain of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT), a heterojunction bipolar transistor (HBT), or other like compound semiconductor transistor. The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, implantation, diffusion, deposition, thermal anneals, and other methods may create the structures and devices of the present disclosure.

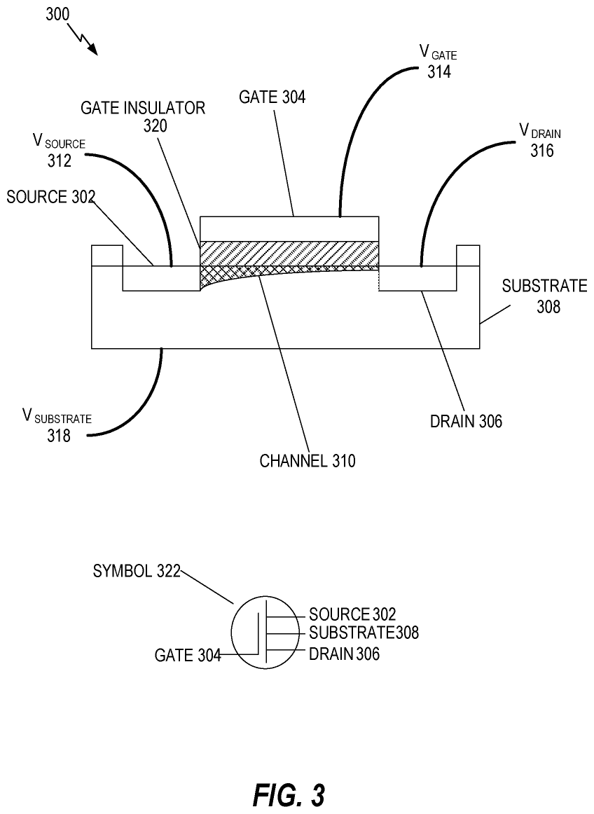

FIG. 3 illustrates a cross-sectional view of a metal oxide semiconductor field-effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in a channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. A gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon”, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers (e.g., 210-214), or may be in other layers of the die 106.

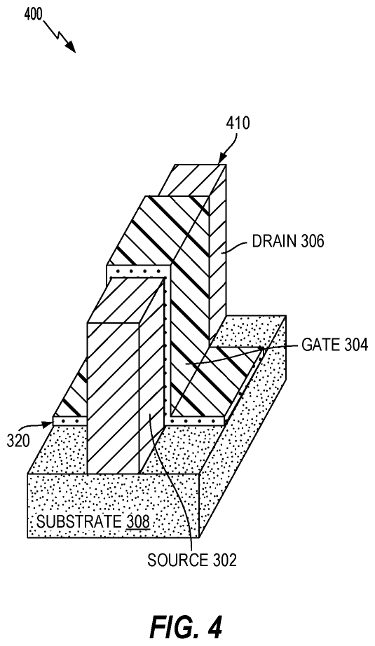

FIG. 4 illustrates a fin-structured FET (FinFET 400) that operates in a similar fashion to the MOSFET device 300 described with respect to FIG. 3. According to aspects of the present disclosure, the FinFET 400 may include multiple gate spacers. A fin 410 in a FinFET 400, however, is grown or otherwise coupled to the substrate 308. The substrate 308 may be a semiconductor substrate or other like supporting layer, for example, comprised of an oxide layer, a nitride layer, a metal oxide layer, or a silicon layer. The fin 410 includes the source 302 and the drain 306. The gate 304 is disposed on the fin 410 and on the substrate 308 through the gate insulator 320. A FinFET transistor is a 3D fin-based metal oxide semiconductor field-effect transistor (MOSFET). As a result, the physical size of the FinFET 400 may be smaller than the MOSFET device 300 structure shown in FIG. 3. This reduction in physical size allows for more devices per unit area on the die 106.

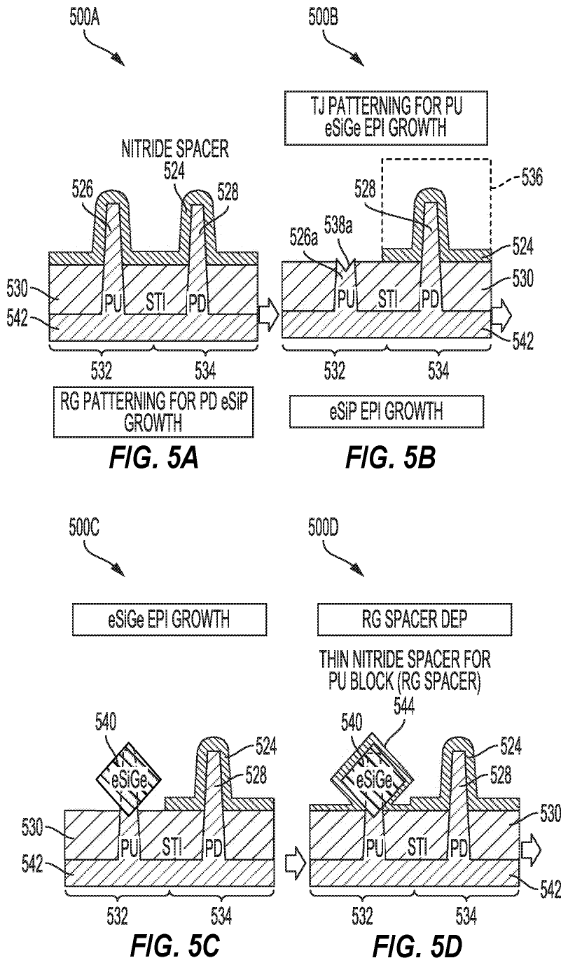

FIGS. 5A-5F are exemplary diagrams illustrating cross-sections of stages of a process of fabricating source/drain regions for a P-type FinFET of an integrated circuit and source/drain regions for an N-type FinFET of the integrated circuit.

Referring to FIG. 5A, a first stage of the process of fabricating source/drain regions of the integrated circuit (e.g., source/drain regions for a P-type FinFET and source/drain regions for an N-type FinFET) is depicted and generally designated 500A. FIG. 5A illustrates fins (e.g., a first fin 526 or raised semiconductor structure and a second fin 528) formed on a substrate 542 (e.g., silicon substrate) with a shallow trench isolation (STI) region 530 between the fins. For example, the STI region 530 is formed on sidewalls of the first fin 526 and the second fin 528 and between the first fin 526 and the second fin 528. A first spacer material 524 is deposited on the first fin 526 and the second fin 528 as well as on the STI region 530. In one aspect, the first spacer material 524 is a nitride spacer. FIG. 5A illustrates a P-type FinFET 532 having P-type regions and an N-type FinFET 534 having N-type regions. Although the P-type FinFET 532 and the N-type FinFET 534 of FIG. 5A actually represent the area where the P-type FinFET 532 and the N-type FinFET 534 are eventually fabricated, for illustrative purposes these areas are referred to as the P-type FinFET 532 and the N-type FinFET 534.

Referring to FIG. 5B, a second stage of the process of fabricating source/drain regions for the P-type FinFET 532 and source/drain regions for the N-type FinFET 534 is depicted and generally designated 500B. One way to fabricate the P-type regions of the P-type FinFET 532 is through patterning. For example, a protection material 536 (e.g., a mask) is formed on the N-type FinFET 534 while the first spacer material 524 on the P-type FinFET 532 and a portion of the first fin 526 within the P-type FinFET 532 are etched down to a surface of the STI region 530. A remaining portion 526a of the first fin 526 is within the STI region 530. A surface 538a of the remaining portion 526a of the first fin 526 may have a ridged shape (e.g., a V shape).

Referring to FIG. 5C, a third stage of the process of fabricating source/drain regions for the P-type FinFET 532 and source/drain regions for the N-type FinFET 534 is depicted and generally designated 500C. FIG. 5C illustrates growing a P-type region 540 on the ridged surface 538a of the P-type FinFET 532. In one aspect of the disclosure, the P-type region 540 is a source/drain region for the P-type FinFET 532 and it is epitaxially grown on the ridged surface 538a. The P-type region 540 may include a P-type source/drain contact such as an embedded silicon germanium (eSiGe) contact.

Referring to FIG. 5D, a fourth stage of the process of fabricating source/drain regions for the P-type FinFET 532 and source/drain regions for the N-type FinFET 534 is depicted and generally designated 500D. FIG. 5D illustrates a second spacer material 544 deposited on the P-type region 540 and the STI region 530. In one aspect of the disclosure, the second spacer material 544 is a nitride spacer that is thin relative to the first spacer material 524.

Referring to FIG. 5E, a fifth stage of the process of fabricating source/drain regions for the P-type FinFET 532 and source/drain regions for the N-type FinFET 534 is depicted and generally designated 500E. FIG. 5E illustrates patterning to fabricate the N-type regions of the N-type FinFET 534. For example, a protection material 546 (e.g., a mask) is formed on the P-type FinFET 532 while the first spacer material 524 on the N-type FinFET 534 and a portion of the second fin 528 within the N-type FinFET 534 are etched down to a surface of the STI region 530. A remaining portion 528a of the second fin 528 is within the STI region 530. A surface 538b of the remaining portion 528a of the second fin 528 may have a ridged shape (e.g., a V shape).

Referring to FIG. 5F, a sixth stage of the process of fabricating source/drain regions for the P-type FinFET 532 and source/drain regions for the N-type FinFET 534 is depicted and generally designated 500F. FIG. 5F illustrates growing an N-type region 548 on the ridged surface 538b of the N-type FinFET 534. In one aspect of the disclosure, the N-type region 548 is a source/drain region for the N-type FinFET and it is epitaxially grown on the ridged surface 538b. The N-type region 548 may include an N-type source/drain contact, such as an embedded silicon phosphide (eSiP) contact.

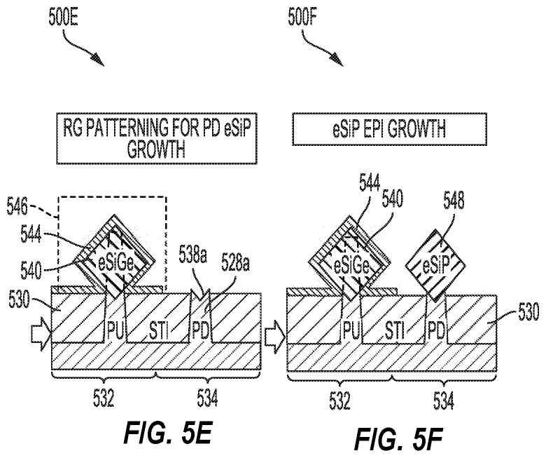

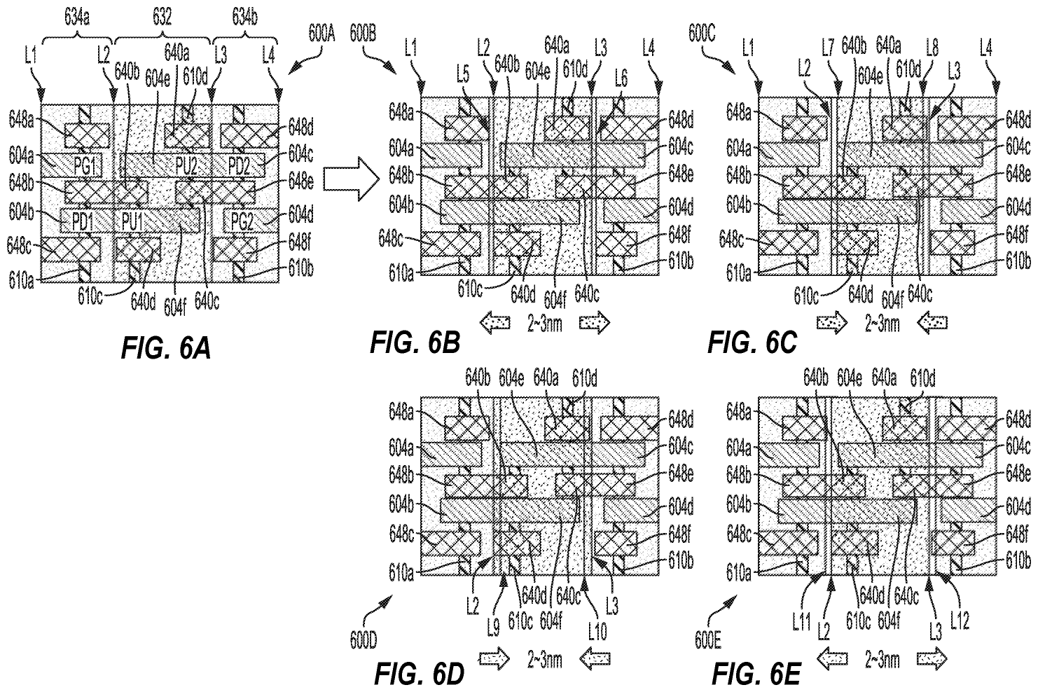

FIG. 6A illustrates a top view of an integrated circuit 600A, designed according to minimum design ground rules or standard technology specifications. The integrated circuit 600A may be a high density memory, such as a static random access memory (SRAM). In one aspect of the disclosure, the integrated circuit 600A may include P-type transistors and N-type transistors in close proximity. For example, the integrated circuit 600A includes a P-type source/drain opening 632 where the source/drain of P-type transistors are formed. The integrated circuit 600A also include, a first N-type source/drain opening 634a, and a second N-type source/drain opening 634b where the source/drain of N-type transistors are formed.

The first N-type source/drain opening 634a includes a first N-type region 648a, a second N-type region 648b, a third N-type region 648c, a first gate region 604a, a second gate region 604b, and a first fin 610a. The second N-type source/drain opening 634b includes a fourth N-type region 648d, a fifth N-type region 648e, a sixth N-type region 648f, a third gate region 604c, a fourth gate region 604d, and a second fin 610b. The P-type source/drain opening 632 includes a first P-type region 640a, a second P-type region 640b, a third P-type region 640c, a fourth P-type region 640d, a fifth gate region 604e, a sixth gate region 604f, a third fin 610c, and a fourth fin 610d. Each of the N-type regions may include an N-type source/drain contact, such as the embedded silicon phosphide (eSiP) contact. Each of the P-type regions may include the P-type source/drain contact, such as the embedded silicon germanium (eSiGe) contact.

The integrated circuit 600A is between a first boundary L1 and a fourth boundary L4. For example, a width of the P-type source/drain opening 632 that conforms to the minimum specified technology ground rule is represented by a distance or spacing between a second boundary L2 and a third boundary L3. A width of the first N-type region 648a that conforms to the minimum specified technology ground rule is represented by a distance between the first boundary L1 and the second boundary L2. A width of the second N-type region 648b that conforms to the minimum specified technology ground rule is represented by a distance between the third boundary L3 and the fourth boundary L4.

As technology scaling continues, associated shrinking of integrated circuit device elements creates latent defects that arise during fabrication of the integrated circuits. Different technologies have different minimum design ground rules that specify a minimum standard distance between the source/drain regions. The transistors designed according to the specified ground rules, however, may have yield issues. The yield issues may stem from a short circuit between two epitaxially grown source/drain regions or between an epitaxially grown source/drain region and a gate region. For example, when the minimum design ground rules specify a minimum distance “x” between two epitaxially grown source/drain regions or between an epitaxially grown source/drain region and a gate region, the integrated circuit is designed such that the distances between the regions are no less than the specified minimum distance “x.”

The short circuit may be caused by a latent defect between the two epitaxially grown source/drain regions separated by the specified minimum distance “x.” This issue may be prominent in very dense devices (e.g., high density memory) that are designed with the minimum design ground rules of a foundry. For example, the latent defect may cause a short between the N-type region 548 and the P-type region 540 when the N-type transistor and the P-type transistor are designed in accordance with the minimum design ground rules. The short can be caused by the N-type region 548 extending toward the P-type region 540 under extreme conditions. For example, high current flowing in the transistor can melt the contacts. The potential for the contacts to short increases with reduction in proximity of the contacts that conform to the minimum design ground rules.

Aspects of the present disclosure are directed to preventing reliability risks by offsetting a distance between the N-type transistor and the P-type transistor below a specified technology ground rule to improve detection of defects or process marginalities.

FIGS. 6B-6G illustrate top views of an integrated circuit where one or more distances between elements of the N-type transistor and the P-type transistor are adjusted below a specified technology ground rule to improve detection of defects or process marginalities. Thus, the design ground rule for minimum spacing of the N-type transistor and the P-type transistor is shrunk beyond the pre-defined standard, according to aspects of the present disclosure, to expedite detection of latent defects. For illustrative purposes, some of the labelling and numbering of the devices and features of FIGS. 6B-6G are similar to those of FIG. 6A.

FIG. 6B is a top view of an integrated circuit 600B where a width of N-type source/drain openings are reduced outside a scope of the specified technology ground rule to improve detection of defects or process marginalities. The width of each of the first N-type source/drain opening 634a and the second N-type source/drain opening 634b of the integrated circuit 600B is reduced relative to that of the integrated circuit 600A. In one aspect, the reduced width of the first N-type source/drain opening 634a and the second N-type source/drain opening 634b of the integrated circuit 600B renders the design of the integrated circuit 600B outside a scope of the specified technology ground rule.

Thus, the width of the first N-type source/drain opening 634a and the second N-type source/drain opening 634b that conforms to the minimum specified technology ground rule is adjusted outside of the scope of the minimum specified technology ground rule to improve detection of defects or process marginalities. For example, the width of the first N-type source/drain opening 634a represented by a distance between the first boundary L1 and the second boundary L2 is adjusted (e.g., reduced by a few nanometers) to a width that is outside a scope of the minimum specified technology ground rule. Similarly, the width of the second N-type source/drain opening 634b represented by a distance between the third boundary L3 and the fourth boundary L4 is adjusted (e.g., reduced by a few nanometers) outside of the scope of the minimum specified technology ground rule.

For example, the boundary L2 between the first N-type source/drain opening 634a and the P-type source/drain opening 632 is adjusted to a boundary L5, and the boundary L3 between the P-type source/drain opening 632 and the second N-type source/drain opening 634b is adjusted to a boundary L6. These adjustments reduce the width of the first N-type source/drain opening 634a and the second N-type source/drain opening 634b by a few nanometers (e.g., two to three nanometers). The reduced width of the first N-type source/drain opening 634a and the second N-type source/drain opening 634b causes the first N-type source/drain opening 634a and the second N-type source/drain opening 634b to fall outside the scope of the minimum specified technology ground rule. In some aspects, a gap between the first P-type region 640a and the fourth N-type region 648d is reduced such that it is less than a minimum specified gap of the minimum specified technology ground rule. As a result, a defect within the gap can be detected earlier than it would otherwise be detected when the integrated circuit 600B conforms to the minimum specified technology ground rule.

FIG. 6C is a top view of an integrated circuit 600C where a width of N-type source/drain openings are increased to cause a misalignment that is outside a scope of the specified technology ground rule in order to improve detection of defects or process marginalities. The width of each of the first N-type source/drain opening 634a and the second N-type source/drain opening 634b of the integrated circuit 600C is increased relative to that of the integrated circuit 600A. In one aspect, the increase in the width of the first N-type source/drain opening 634a and the second N-type source/drain opening 634b of the integrated circuit 600C renders the design of the integrated circuit 600C outside a scope of the specified technology ground rule. For example, the boundary L2 between the first N-type source/drain opening 634a and the P-type source/drain opening 632 is adjusted to a boundary L7, and the boundary L3 between the P-type source/drain opening 632 and the second N-type source/drain opening 634b is adjusted to a boundary L8. These adjustments in distance between some of the source/drain regions of the first N-type source/drain opening 634a (and/or the second N-type source/drain opening 634b) and the source/drain regions of the P-type source/drain opening 632 may fall outside of the scope of the specified technology ground rule.

FIG. 6D is a top view of an integrated circuit 600D where a width of the P-type source/drain opening 632 is reduced outside a scope of the specified technology ground rule to improve detection of defects or process marginalities. The width of the P-type source/drain opening 632 of the integrated circuit 600D is reduced relative to that of the integrated circuit 600A. For example, the boundary L2 between the first N-type source/drain opening 634a and the P-type source/drain opening 632 is adjusted to a boundary L9, and the boundary L3 between the P-type source/drain opening 632 and the second N-type source/drain opening 634b is adjusted to a boundary L10. The reduced width of the P-type source/drain opening 632 of the integrated circuit 600D renders the design of the integrated circuit 600D outside a scope of the specified technology ground rule. For example, a gap between the fourth P-type region 640d and the third N-type region 648c is reduced such that it is less than a minimum specified gap of the minimum specified technology ground rule. As a result, a defect within the gap can be detected earlier than it would otherwise be detected when the integrated circuit 600D conforms to the minimum specified technology ground rule.

FIG. 6E is a top view of an integrated circuit 600E where a width of the P-type source/drain opening 632 is increased. In some aspects, the width of the P-type source/drain opening 632 of the integrated circuit 600E is increased at the expense of the first N-type source/drain opening 634a and/or the second N-type source/drain opening 634b. For example, the width of the first N-type source/drain opening 634a and/or the second N-type source/drain opening 634b is reduced (as shown with respect to FIG. 6B) such that some of the parameters of the integrated circuit 600E fall outside the scope of the specified technology ground rule.

Thus, the boundary L2 between the first N-type source/drain opening 634a and the P-type source/drain opening 632 is adjusted to a boundary L11, and the boundary L3 between the P-type source/drain opening 632 and the second N-type source/drain opening 634b is adjusted to a boundary L12. These adjustments reduce the width of the first N-type source/drain opening 634a and the second N-type source/drain opening 634b of the integrated circuit 600E by a few nanometers (e.g., two to three nanometers) while increasing the width of the P-type source/drain opening 632 of the integrated circuit 600E.

As technology shrinks (e.g., from fourteen nanometer to ten nanometer to seven nanometer, etc.) the latent defects are prone to increase. Some of the latent defects are caused when a gate material (e.g., hafnium) diffuses into or starts to diffuse toward the source/drain regions or the contact regions of the integrated circuit. This diffusion of the gate material causes a short in the integrated circuit.

Some aspects of the present disclosure mitigate gate-to-contact shorts and gate-to-source/drain region shorts by adjusting (e.g., reducing) a distance between the gates and the contacts or the distance between the gate and the source/drain regions. For example, the distances may be reduced outside the scope of the specified technology ground rule.

FIG. 6F and FIG. 6G are top views of an integrated circuit 600F and 600G where a separation of a gate region from source/drain regions is adjusted, relative to the separation illustrated in FIG. 6A, to expedite detection of latent defects, according to aspects of the present disclosure. The gate region may be sandwiched between two source/drain regions. For example, the third gate region 604c is sandwiched between the fourth N-type region 648d and the fifth N-type region 648e. In one aspect, the separation of the gate region from source/drain regions may be adjusted such that the separation is outside a scope of the specified technology ground rule.

In FIG. 6F, a source/drain region or a corresponding source/drain region contact of the source/drain region is misaligned relative to a gate region or a corresponding gate contact of the gate region. For example, the third gate region 604c may be adjusted by moving the third gate region 604c towards the fourth N-type region 648d and away from the fifth N-type region 648e. Thus, the separation between the third gate region 604c and the fourth N-type region 648d is reduced while the separation between the third gate region 604c and the fifth N-type region 648e is increased. For example, the third gate region 604c may be shifted between two to three nanometers toward the fourth N-type region 648d and away from the fifth N-type region 648e. This causes the separation between the third gate region 604c and the fourth N-type region 648d to be reduced by two to three nanometers while the separation between the third gate region 604c and the fifth N-type region 648e is increased by two to three nanometers.

In FIG. 6G, the third gate region 604c may be adjusted by moving the third gate region 604c away from the fourth N-type region 648d and toward the fifth N-type region 648e. Thus, the separation between the third gate region 604c and the fourth N-type region 648d is increased while the separation between the third gate region 604c and the fifth N-type region 648e is reduced. For example, the third gate region 604c may be shifted between two to three nanometers away from the fourth N-type region 648d and toward the fifth N-type region 648e. This causes the separation between the third gate region 604c and the fourth N-type region 648d to increase by two to three nanometers while the separation between the third gate region 604c and the fifth N-type region 648e to reduce by two to three nanometers.

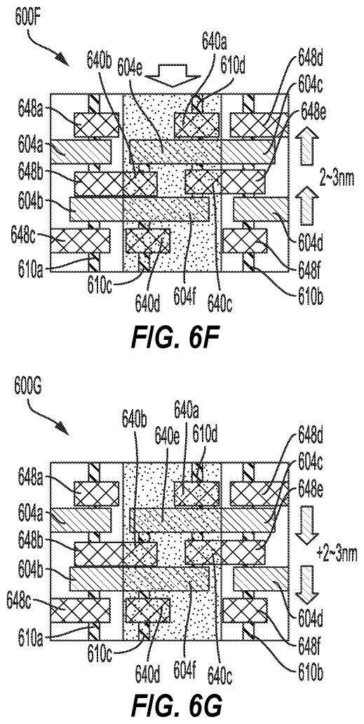

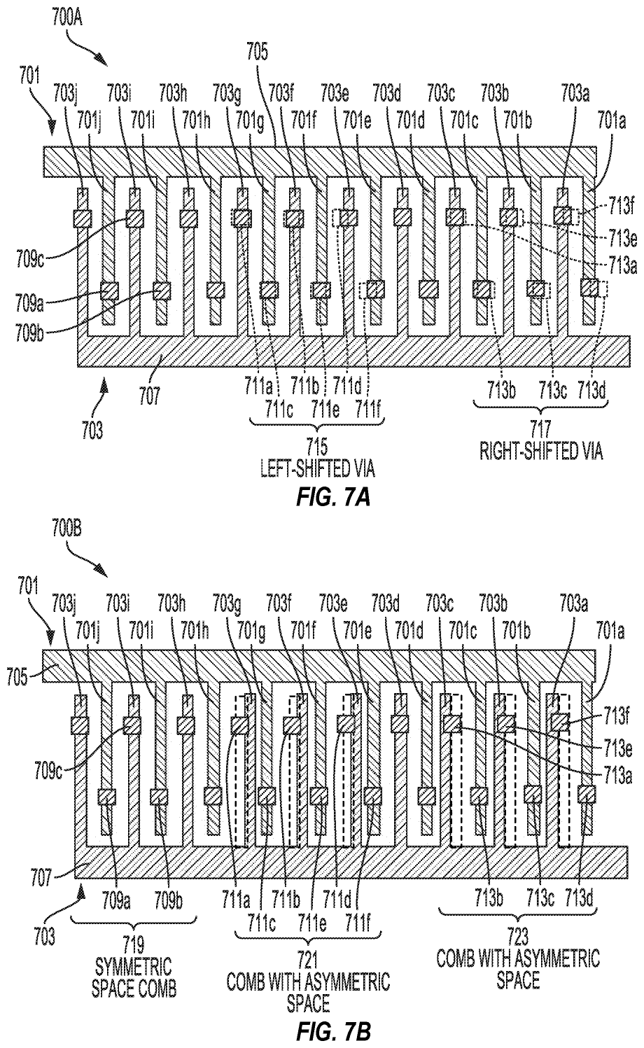

FIG. 7A illustrates an on-chip test structure 700A having a double comb structure where vias associated with conductive branches of the comb structure are misaligned, according to aspects of the present disclosure. In one aspect, the on-chip test structure 700A is part of conductive contact structure of a chip that is included in one or more middle-of-line of back-end-of-line layers of the chip. For example, the on-chip test structure 700A includes conductive contacts coupled to one or more of the source/drain regions of the chip and/or coupled to one or more of the gates of the chip.

The double comb on-chip test structure 700A provides early detection of extra material defects (e.g., residual traces of unwanted metal) that cause unwanted short circuits in the chip. The on-chip test structure 700A includes two isolated conductive combs (e.g., a first conductive comb 701 and a second conductive comb 703) with interdigitated branches. For example, the first conductive comb 701 includes a first set of conductive branches 701a-701j orthogonally coupled to a first conductive terminal 705. The second conductive comb 703 includes a second set of conductive branches 703a-703j orthogonally coupled to a second conductive terminal 707. The first set of conductive branches 701a-701j is interdigitated with the second set of conductive branches 703a-703j.

The first conductive comb 701 and the second conductive comb 703 are situated over various wafer terrains to ensure that residual traces of unwanted metal do not exist. The wafer terrains includes metal and polysilicon interconnects that form the transistors and their corresponding connections. For example, to test the on-chip test structure 700A, a voltage or current is applied to the first conductive terminal 705 and current or voltage is sensed at the second conductive terminal 707. A significant current or voltage above some noise floor indicates a short between the first conductive comb 701 and the second conductive comb 703.

Conventionally, the conductive branches and the vias of an on-chip test structure (e.g., a double comb structure) are uniformly aligned and within the scope of the specified technology ground rule. For example, a separation between each of the conductive branches and/or the vias of the double comb structure are substantially the same. The conventional arrangement, however, fails to achieve early detection of latent defects that eventually cause a short. Accordingly, it is desirable to provide an on-chip test structure that expedites detection of latent defects.

The on-chip test structure 700A expedites detection of latent defects by adjusting vias coupled to the on-chip test structure 700A to misalign the via positions on the conductive branches of the on-chip test structure 700A. Thus, at least a subset of the vias are offset relative to other vias that are configured according to a standard technology specification. In some aspects, the adjustment of the vias on the conductive branches causes the placement of the adjusted vias to be outside a scope of the specified technology ground rule or the standard technology specification. Thus, the design ground rule for minimum offset of the vias is adjusted beyond the standard according to aspects of the present disclosure to expedite detection of latent defects.

For example, to expedite the detection of the latent defects, some of the positions of the vias are adjusted to the right and/or some of the vias are adjusted to the left. For example, vias 711a, 711b, 711c 711d, 711e, and 711f in a region 715 are shifted to the left as indicated by the dashed lines. A distance of the left shift of each of the vias in the region 715 may be the same or different. Vias 713a, 713b, 713c 713d, 713e, and 713f in a region 717 are shifted to the right as indicated by the dashed lines. A distance of the right shift of each of the vias in the region 717 may be the same or different. Other vias (e.g., 709a, 709b, and 709c) may remain un-shifted.

FIG. 7B illustrates an on-chip test structure 700B having a double comb structure where the fingers or conductive branches of the comb structure are misaligned, according to aspects of the present disclosure. For illustrative purposes, some of the labelling and numbering of the devices and features of FIG. 7B are similar to those of FIG. 7A. For example, rather than shifting the positions of the vias, as in FIG. 7A, the conductive branches of the on-chip test structure 700B are shifted. Any shift in the vias, in this case, is a consequence of the shifting of the conductive branches.

Some of the conductive branches of one or more of the conductive branches of the first conductive comb 701 and/or the second conductive comb 703 may be shifted or adjusted to expedite detection of latent defects. In some aspects, adjusting the conductive branches renders the double comb structure of the on-chip test structure 700B asymmetric and/or outside the scope of the specified technology ground rule. In one aspect, the first set of conductive branches 701a-701j and/or the second set of conductive branches 703a-703j have a branch to branch distance variation. Thus, in some aspects, the design ground rule for minimum spacing of the conductive branches is shrunk to expedite detection of latent defects.

For example, the conductive branches 703e, 703f, and 703g of the second conductive comb 703 in a region 721 are shifted to the left as indicated by the dashed lines, which causes the comb structure with respect to the region 721 to be asymmetric. A distance of the left shift of each of the conductive branches 703e, 703f, and 703g in the region 721 may be the same or different. The corresponding vias (e.g., vias 711a, 711b, and 711d) on the conductive branches 703e, 703f, and 703g are also shifted with the conductive branches 703e, 703f, and 703g.

The conductive branches 703a, 703b, and 703c of the second conductive comb 703 in a region 723 are shifted to the right as indicated by the dashed lines, which causes the comb structure with respect to the region 723 to be asymmetric. A distance of the right shift of each of the conductive branches 703a, 703b, and 703c in the region 723 may be the same or different. The corresponding vias (e.g., vias 713a, 713e, and 713f) on the conductive branches 703a, 703b, and 703c are also shifted with the conductive branches 703a, 703b, and 703c. Other conductive branches (e.g., conductive branches 703h, 703i, and 703j) may remain un-shifted and therefore symmetric. The on-chip test structure 700A and the on-chip test structure 700B may be implemented on a product chip, a foundry test-chip, or an original equipment manufacturer test-chip.

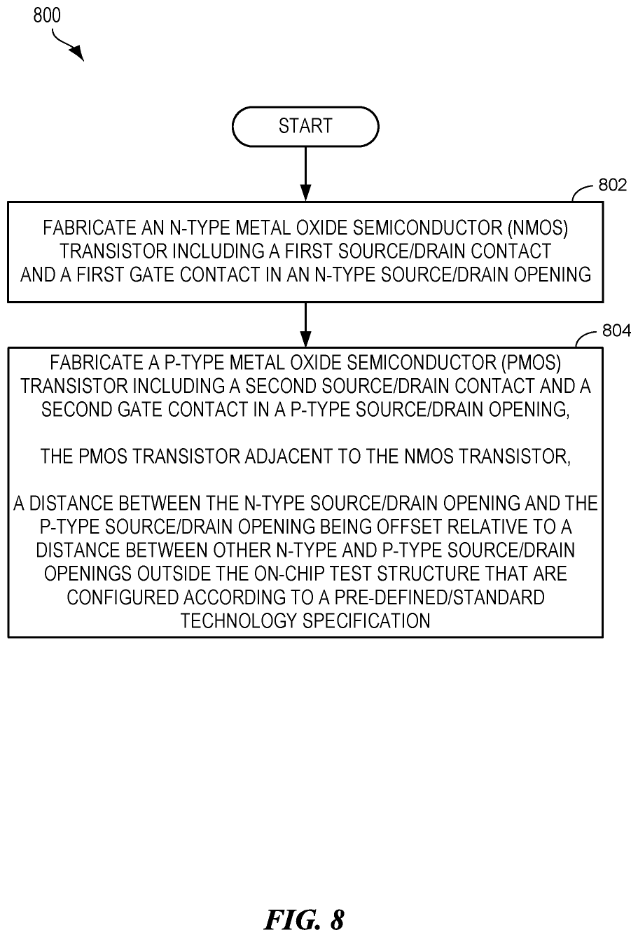

FIG. 8 is a flow diagram illustrating a method 800 of fabricating a conductive test structure, in accordance with aspects of the present disclosure. The blocks in the method 800 may be performed in or out of the order shown, and in some aspects, can be performed at least in part in parallel.

At block 802, an N-type metal oxide semiconductor (NMOS) transistor including a first source/drain contact and a first gate contact is fabricated in an N-type source/drain opening. At block 804 a P-type metal oxide semiconductor (PMOS) transistor including a second source/drain contact and a second gate contact is fabricated in a P-type source/drain opening. The PMOS transistor is adjacent to the NMOS transistor. A distance between the N-type source/drain opening and the P-type source/drain opening is offset relative to a distance between other N-type source/drain openings and P-type source/drain openings outside the on-chip test structure that are configured according to a standard technology specification.

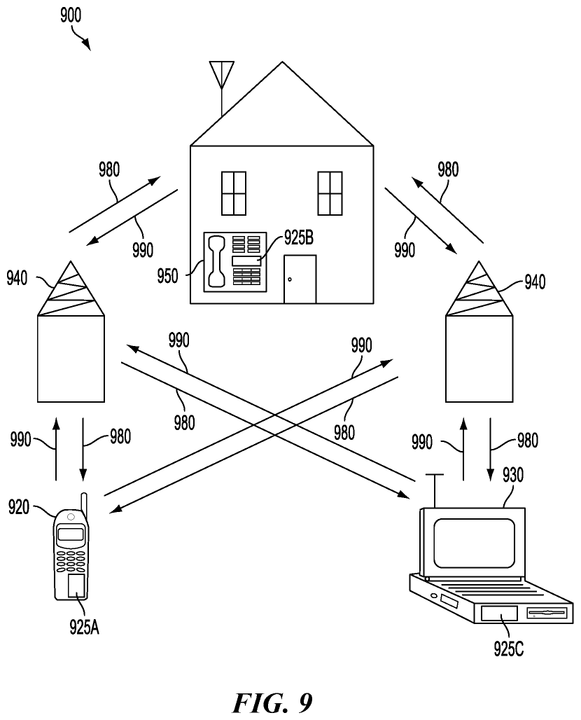

FIG. 9 is a block diagram showing an exemplary wireless communications system 900 in which an aspect of the disclosure may be advantageously employed. For purposes of illustration, FIG. 9 shows three remote units 920, 930, and 950 and two base stations 940. It will be recognized that wireless communications systems may have many more remote units and base stations. Remote units 920, 930, and 950 include IC devices 925A, 925C, and 925B that include at least a portion of the on-chip test structure. It will be recognized that other devices including the on-chip test structure may also be included in, for example, base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices including the on-chip test structure.

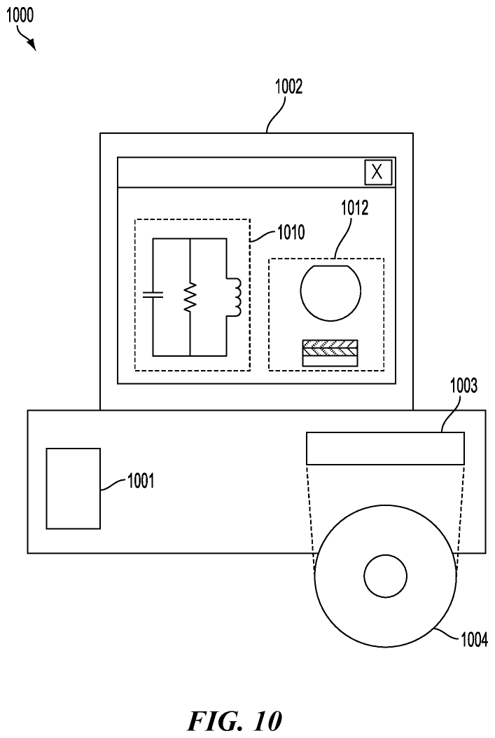

FIG. 10 is a block diagram illustrating a design workstation used for circuit, layout, and logic design of a semiconductor component tested using the on-chip test structure disclosed above. A design workstation 1000 includes a hard disk 1001 containing operating system software, support files, and design software such as Cadence or OrCAD. The design workstation 1000 also includes a display 1002 to facilitate a circuit design 1010 or a chip having the on-chip test structure. A storage medium 1004 is provided for tangibly storing the circuit design 1010 including an on-chip test structure design 1012. The circuit design 1010 including the on-chip test structure design 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit design 1010 or the on-chip test structure design 1012 by decreasing the number of processes for designing semiconductor wafers.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communications networks and/or communications technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. Also, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described herein generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described herein may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. An on-chip test structure comprising:
an NMOS transistor (N-type metal oxide semiconductor transistor) including a first source/drain contact and a first gate contact is formed in an N-type source/drain opening; and
a PMOS transistor (P-type metal oxide semiconductor transistor) adjacent to the NMOS transistor, the PMOS transistor including a second source/drain contact and a second gate contact formed in a P-type source/drain opening, a distance between the N-type source/drain opening and the P-type source/drain opening being offset relative to a distance between other N-type source/drain openings and P-type source/drain openings, outside the on-chip test structure, that are configured according to a standard technology specification.

2. The on-chip test structure of claim 1, in which a width of the N-type source/drain opening is reduced outside of a scope of the standard technology specification to offset the distance between the N-type source/drain opening and the P-type source/drain opening.

3. The on-chip test structure of claim 1, in which a width of the P-type source/drain opening is reduced outside of a scope of the standard technology specification to offset the distance between the N-type source/drain opening and the P-type source/drain opening.

4. The on-chip test structure of claim 1, in which a distance between the first source/drain contact and the second source/drain contact is reduced.

5. The on-chip test structure of claim 1, in which the first source/drain contact is misaligned relative to the first gate contact.

6. The on-chip test structure of claim 1, in which the second source/drain contact is misaligned relative to the second gate contact.

7. An on-chip test structure comprising:
a conductive contact structure in a conductive layer of a metal oxide semiconductor (MOS) transistor, the conductive contact structure comprising:
a first set of conductive branches orthogonally coupled to a first conductive terminal; and
a second set of conductive branches orthogonally coupled to a second conductive terminal, the first set of conductive branches interdigitated with the second set of conductive branches, the first set of conductive branches and/or the second set of conductive branches having branch to branch distance variation.

8. The on-chip test structure of claim 7, in which at least a subset of the first set of conductive branches are shifted to the left or to the right to vary the branch to branch distance of the first set of conductive branches.

9. The on-chip test structure of claim 7, in which at least a subset of the second set of conductive branches are shifted to the left or to the right to vary the branch to branch distance of the second set of conductive branches.

10. The on-chip test structure of claim 7, in which the conductive layer comprises a back-end-of-line (BEOL) layer or a middle-of-line (MOL) layer.

11. The on-chip test structure of claim 7, in which the conductive layer comprises gate contacts or source/drain contacts.

12. An on-chip test structure comprising:
a conductive contact structure in a conductive layer of a metal oxide semiconductor (MOS) transistor, the conductive contact structure comprising:
a first set of conductive branches orthogonally coupled to a first conductive terminal;
a second set of conductive branches orthogonally coupled to a second conductive terminal, the first set of conductive branches interdigitated with the second set of conductive branches; and
vias connected to the first set of conductive branches and the second set of conductive branches, a subset of the vias being offset relative to other vias that are configured according to a standard technology specification.

13. The on-chip test structure of claim 12, in which the subset of the vias are shifted to the left or to the right to offset the subset of the vias relative to the other vias.

14. The on-chip test structure of claim 12, in which the conductive layer comprises a back-end-of-line (BEOL) layer or a middle-of-line (MOL) layer.

15. A method of making an on-chip test structure comprising:
fabricating an NMOS transistor (N-type metal oxide semiconductor transistor) including a first source/drain contact and a first gate contact in an N-type source/drain opening; and
fabricating a PMOS transistor (P-type metal oxide semiconductor transistor) adjacent to the NMOS transistor, the PMOS transistor including a second source/drain contact and a second gate contact in a P-type source/drain opening, a distance between the N-type source/drain opening and the P-type source/drain opening being offset relative to a distance between other N-type source/drain openings and P-type source/drain openings, outside the on-chip test structure, that are configured according to a standard technology specification.

16. The method of claim 15, further comprising reducing a width of the N-type source/drain opening outside of a scope of the standard technology specification to offset the distance between the N-type source/drain opening and the P-type source/drain opening.

17. The method of claim 15, further comprising reducing a width of the P-type source/drain opening outside of a scope of the standard technology specification to offset the distance between the N-type source/drain opening and the P-type source/drain opening.

18. The method of claim 15, further comprising reducing a distance between the first source/drain contact and the second source/drain contact.

19. The method of claim 15, further comprising misaligning the first source/drain contact relative to the first gate contact.

20. The method of claim 15, further comprising misaligning the second source/drain contact relative to the second gate contact.
